(19) United States
(12) Patent Application Publication
(10) Pub. No.: US 2009/0009217 A1
(43) Pub. Date: Jan. 8, 2009

(54) TRANSFORMATION OF AN INPUT SIGNAL INTO A LOGICAL OUTPUT VOLTAGE LEVEL WITH A HYSTERESIS BEHAVIOR

(75) Inventors: Albert Jan Huitsing, Nijmegen (NL); Louw Hoefnagel, Veenendaal (NL); Thierry Jans, Uden (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/278,668

(22) PCT Filed: Feb. 13, 2007
(86) PCT No.: PCT/IB07/50463

§ 371 Date: Aug. 7, 2008

(30) Foreign Application Priority Data
Feb. 16, 2006 (EP) 06110022.8

(51) Int. Cl. H03K 19/0185; H03K 19/00

(52) U.S. Cl. 326/68; 326/119; 326/80

(57) ABSTRACT

It is described a circuit and a method for transforming an input signal into a logical output. The circuit (100) comprises an inverter stage (120), connected in between the first conductor (101) and the second conductor (102). The inverter stage (120) includes a MOS switch (MP0), which comprises a first terminal being connected to the first conductor (101), a second terminal being connected to an output node (hyst), a gate terminal being connected to an input node (JN), and a back gate terminal. The circuit (100) further comprises a voltage divider (130), connected in between the first conductor (101) and the output node (hyst), wherein the voltage divider (130) provides a divider output node (bg) being connected to the back gate terminal. The circuit (100) represents an input cell having an improved hysteresis behavior over the total operating voltage range. This is achieved by adjusting the back gate voltage of the MOS switch (MP0) during a transition from an input level Low to an input level High. This causes a temporarily increased threshold voltage for turning off the MOS switch (MP0) during the transition.

### FIELD OF THE INVENTION

The present invention relates to the field of electronic circuits, which perform a signal transformation from an input signal representing an input voltage level into a logical output voltage level. In particular, the present invention relates to such electronic circuits wherein the logical output voltage level comprises a hysteresis behavior when the input signal performs a sweeping change within a voltage range representing a plurality of possible input voltage levels.

### BACKGROUND OF THE INVENTION

In designing digital circuits and systems, noise immunity and stability, are important criteria. For example, an input digital signal to a digital switching circuit that contains noise may cause the digital switching circuit to transition to a different state due to the noise and not due to the informational content of the signal. To prevent multiple triggering of the digital circuit and to provide noise immunity, digital switching circuits often employ a hysteresis behavior. In general, a circuit utilizing electrical hysteresis generates an output based on both an input and on the recent history of the circuit. In a digital circuit employing hysteresis, once a first state transition occurs, the circuit requires a different signal trip point to cause a transition to a second state. The difference in the input signal required to generate the second state transition in the circuit is defined as the amount of hysteresis. A particular amount of hysteresis for a digital circuit is dependent upon the particular application. A typical design value for hysteresis is 150 mV, where the input transition point for switching from a High state to a Low state is 150 mV less than for the input transition point for switching from the Low state to the High state.

U.S. Pat. No. 6,433,602 B1 discloses a CMOS Schmitt Trigger circuit design providing a relatively high speed device having a tight, substantially monotonic hysteresis characteristic which is substantially independent of fabrication process parameters and can be used with relatively wide power supply designs, including operating a relatively low Vcc. Tight trip point variation is maintained in conjunction with process, voltage, and temperature changes. The circuit is adaptable for forming an integrated circuit buffer element. However, the disclosed CMOS Schmitt Trigger circuit exhibits the disadvantage that in particular at low operating voltages Vcc the hysteresis behavior is limited such that noisy input signals might cause a multiple triggering of the Trigger circuit.

### OBJECT AND SUMMARY OF THE INVENTION

There may be a need for a circuit and a method for transforming an input signal into a logical output voltage level with an improved hysteresis behavior in particular at low operating voltages.

This need may be met by an electronic circuit arrangement and by a method as set forth in the independent claims.

According to a first aspect of the invention there is provided an electronic circuit arrangement for transforming an input signal into a logical output voltage level. The electronic circuit arrangement comprises a first conductor adapted to be connected to an operating voltage level and a second conductor adapted to be connected to a reference voltage level. The circuit arrangement further comprises an inverter stage, which is connected in between the first conductor and the second conductor. The inverter stage includes a MOS switch element, which comprises (a) a first terminal being connected to the first conductor, (b) a second terminal being connected to an output node, (c) a gate terminal being connected to an input node, and (d) a back gate terminal. Furthermore, the circuit arrangement comprises a voltage divider, which is connected in between the first conductor and the output node. The voltage divider is adapted to provide a divider output node being connected to the back gate terminal.

This aspect of the invention is based on the idea that by adjusting the back gate voltage level of the MOS switch element in particular during a transition from an input level Low to an input level High, an improved hysteresis behavior may be obtained. This improved hysteresis behavior is characterized by two significantly different threshold values for the transition from an input level Low to an input level High and for a transition from an input level High to an input level Low, respectively. The improved hysteresis behavior may be achieved within a wide rage of operating or supply voltages. By contrast to hysteresis behaviors of known circuit arrangements the hysteresis behavior of the described electronic circuit arrangement is enhanced in particular for small operating voltage levels.

It has to be noted that according to the aspect described above the output node exhibits an inverted signal with respect to the signal being applied to the input node.

The described electronic circuit arrangement may be used as an input cell for a variety of different electronic devices, which require a precisely defined logical input. For instance, the described circuit arrangement may be used as an input cell for the so-called Advanced Ultra-low Power (AUP) Complementary Metal Oxide Semiconductor (CMOS) logic family, which is manufactured by Philips Semiconductors (Eindhoven, Netherlands). The AUP reduces power consumption and board space by more than 30 percent compared to electronic modules, which are used for similar applications. This allows for an extended battery life in modern electronic devices such as cell phones, Personal Digital Assistants, digital cameras, and video players.

The AUP logic family comprises single-, dual-, and triple-gate functions housed in a 5-, 6-, and 8-pin packaging allowing engineers to select the exact functions they require. Typical specifications for the AUP logic family are: operating voltage range 0.8V to 3.6V, propagation delays of 2.5 ns at 2.5V, and a Capacitance Power Dissipation of 4 pF or less.

According to an embodiment of the present invention as set forth in claim 2, the MOS switch element is a p-channel MOSFET, the source of which is connected to the first conductor and the drain of which is connected to the output node. A Metal Oxide Semiconductor Field Effect Transistor (MOSFET) has the advantage that the gate terminal is electrically isolated from the other terminals of the MOS switch element. Therefore, there is practically no leakage current flowing off the gate terminal such that the impedance of the input cell is very high.

According to a further embodiment of the invention as set forth in claim 3, the inverter stage includes a further MOS switch element, which comprises (a) a first terminal being connected to the output node, (b) a second terminal being connected to the reference voltage level, and (c) a gate terminal being connected to the input node. A back gate terminal of the further MOS switch element may be connected to the reference voltage level.

According to a further embodiment of the invention as set forth in claim 4, the MOS switch element is an n-channel MOSFET, the drain of which is connected to the output node and the source of which is connected to the second conductor. According to this embodiment the first inverter stage represents a CMOS inverter. This has the benefit that there is always one MOS switch element closed such that a static current flowing from the first conductor to the second connector is significantly reduced. Therefore, the power dissipation of the input cell is also reduced significantly.

According to a further embodiment of the invention as set forth in claim 5, the voltage divider comprises an upper circuit portion, connected in between the first conductor and the divider output node, and a lower circuit portion, connected in between the divider output node and the output node. Thereby, the upper circuit portion includes an upper switch element, which comprises (a) a first terminal being connected to the first conductor, (b) a second terminal being connected to the divider output node, and (c) a gate terminal being connected to the output node. A back gate terminal of the second MOS switch element may be connected to the reference voltage level.

According to a further embodiment of the invention as set forth in claim 6, the upper switch element is a p-channel MOSFET, the source of which is connected to the first conductor and the drain of which is connected to the divider output node. As has been mentioned already above, a MOSFET has the advantage that there is practically no leakage current flowing off the gate terminal such that the impedance of the input cell is very high.

According to a further embodiment of the invention as set forth in claim 7, the lower circuit portion includes a lower switch element, which comprises (a) a first terminal being connected to the divider output node, (b) a second terminal being connected to the output node, and (c) a gate terminal being connected to a node, which comprises a voltage level representing a logical inverted signal of the signal being present at the output node.

According to this embodiment the gates of both switch elements, the upper switch element and the lower switch element, respectively, are both connected directly or indirectly to the output node. Therefore, the effective voltage division and also the voltage level of the divider output node depend strongly on the updated and momentary voltage level of the output node. This means, that the voltage divider represents a feedback loop for adjusting the voltage level, which is applied to the back gate of the MOS switch element.

This feedback loop has the effect that during a transition from an input level Low to an input level High the voltage level of the divider output node is temporarily lowered. Since the divider output node is connected to the back gate terminal of the MOS switch element, the threshold voltage of the MOS switch element is temporarily increased. Therefore, the hysteresis of the electronic circuit arrangement is enhanced making the described electronic circuit arrangement a very reliable input cell for downstream logical devices.

It has to be pointed out that the lower switch element may be a normal PMOS device that creates a Schmitt Trigger-like action.

Further, it has to be pointed out that according to the embodiment described here the upper switch element generates a the back gate voltage level biasing itself, biasing the MOS switch element and biasing the lower switch element.

According to a further embodiment of the invention as set forth in claim 8, the lower switch element is a p-channel MOSFET, the source of which is connected to the divider output node and the drain of which is connected to the output node. As has been mentioned already above, a MOSFET switching device has the advantage that there is practically no leakage current flowing off the gate terminal. Since the gate terminal is being connected with the final output node there is no unwanted increase of the output impedance due to the feedback loop represented by the voltage divider.

According to a further embodiment of the invention as set forth in claim 9, the upper circuit portion includes a diode, which is connected in parallel to the upper switch element. The anode of the diode is connected to the first conductor whereas the cathode of the diode is connected to the divider output node.

The diode has the impact that the divider output node, which is connected to the back gate terminal of the MOS switch element, is prevented to become a floating node. Therefore, the back gate terminal of the MOS switch element is always connected to a stable voltage level such that the described electronic circuit arrangement represents a reliable transformer of an input signal into a logical output voltage level.

According to a further embodiment of the invention as set forth in claim 10, the electronic circuit arrangement further comprises an additional inverter stage, connected in between the first conductor and the second conductor. The additional inverter stage includes an additional MOS switch element, which comprises (a) a first terminal being connected to the first conductor, (b) a second terminal being connected to a final output node, and (c) a gate terminal being connected to the output node.

The additional inverter stage has the advantage that the logical signal being present at the final output node is not inverted with respect to the input node. Therefore, the signal being present at the final output node may used as an input signal for the gate terminal of the lower switch element.

According to a further embodiment of the invention as set forth in claim 11, the additional MOS switch element is a p-channel MOSFET, the source of which is connected to the first conductor and the drain of which is connected to the final output node.

The use of a MOSFET has the advantage that there is practically no current, which is being drawn from the output node. Therefore, no current flow has to be generated by the first inverter stage and/or the voltage divider, respectively.

According to a further embodiment of the invention as set forth in claim 12, the additional inverter stage includes a further additional MOS switch element, which comprises (a) a first terminal being connected to the final output node, (b) a second terminal being connected to the reference voltage level, and (c) a gate terminal being connected to the output node. This has the advantage that also within the second inverter stage there are arranged two additional MOS switch elements in series in between the first and the second conductor, respectively. Therefore, the static current, which is flowing through these two additional MOS switch elements may be reduced.

According to a further embodiment of the invention as set forth in claim 13, the further additional MOS switch element is an n-channel MOSFET, the drain of which is connected to the final output node and the source of which is connected to the second conductor. This has the advantage that also the additional inverter stage represents a CMOS inverter. Therefore, there is always one MOS switch element closed such that a static current flowing from the first conductor to the second connector may be further reduced. This provides the benefit that the corresponding power dissipation, which is generated within the additional inverter stage, can be neglected such that the static currents within the whole input cell are not increased.

According to a further embodiment of the invention as set forth in claim 14, the electronic circuit arrangement further comprises a first Electro Static Discharge protection extending between the input node and the second conductor. The first Electro Static Discharge (ESD) protection may be accomplished by means of an ESD protection diode and/or by means of a switching element. In the latter case preferably an n-channel MOSFET is used, the gate and the source of which being connected. It has to be pointed out that there are many other ways to implement an ESD protection.

According to a further embodiment of the invention as set forth in claim 15, the electronic circuit arrangement further comprises a second Electro Static Discharge protection extending between a leadoff input node and the second conductor. The leadoff input node is adapted to be connected to an input signal to the electronic circuit arrangement. Further, the leadoff input node and the input node are connected to each other via a resistor. This has the advantage that an in particular reliable and loadable ESD protection may be provided. Therefore, the described input cell and, as a consequence, also a downstream logic devices are less vulnerable to static electricity.

It has to be mentioned that also the second ESD protection may be accomplished by means of an ESD protection diode and/or by means of a switching element as has been described above.

The above-mentioned need may further be met by a method for transforming an input signal into a logical output voltage level as set forth in claim 16. The method comprises a first step of applying an input signal to an input node, the input node being connected to an inverter stage, which is connected in between a first conductor being at an operating voltage level and a second conductor being at a reference voltage level. The inverter stage includes a MOS switch element, which comprises (a) a first terminal being connected to the first conductor, (b) a second terminal being connected to an output node, (c) a gate terminal being connected to the input node, and (d) a back gate terminal. The described method further comprises a second step of temporarily lowering the voltage level of a divider output node being connected to the back gate terminal of the MOS switch element such that the threshold voltage of the MOS switch element is temporarily increased. The second step is carried out when the input signal accomplishes a transition from an input level Low to an input level High.

This aspect of the invention is based on the idea that the back gate voltage level of the MOS switch element may temporarily be adjusted in particular during a transition from an input level Low to an input level High. Thereby, an improved hysteresis behavior may be generated showing two different threshold values for the transition from an input level Low to an input level High and for a transition from an input level High to an input level Low, respectively.

The described method has the advantage that an improved hysteresis behavior may be generated. This applies within a wide rage of operating voltages from minimal to maximum operating voltages.

The enhanced hysteresis behavior has the advantage that even if the input signal exhibits a corrugated and/or undulated transition from an input level Low to an input level High, an unwanted oscillation of a signal being present at the output node may be prevented. Therefore, the described method shows a Schmitt Trigger-like behavior with significantly different threshold voltages for different direction of logical transitions.

According to an embodiment of the invention as set forth in claim 17, the method further comprises the step of generating the voltage level of the divider output node by means of a voltage division between the operating voltage level and the voltage level being present at the output node.

According to a further embodiment of the invention as set forth in claim 18, the step of generating the voltage level of the divider output node is carried out by means of a voltage divider, the voltage divider comprising an upper circuit portion, connected in between the first conductor and the divider output node, and a lower circuit portion, connected in between the divider output node and the output node. The voltage divider may be realized with different embodiments, some of which have already been described above.

According to a further embodiment of the invention as set forth in claim 19, the method further comprises the steps of (a) inverting the voltage level being present at the output node and (b) providing the inverted voltage level at a final output node. The step of inverting may be carried out by means of an additional inverter stage. Preferably, also the additional inverter stage may be power-supplied by the operating voltage and the reference voltage.

The inverted voltage level may be provided for downstream logic devices, which are connected to a final output node exhibiting the inverted voltage level. Therefore, the described method represents a procedure performed by a transceiver, which outputs a stable and reliable logical value not being inverted with respect to the signal being present at the input node.

According to a further embodiment of the invention as set forth in claim 20, the method further comprises the step of protecting the input node from Electro Static Discharge currents. The ESD protection may be carried out by means of an ESD protection branch comprising an ESD protection device like a diode or a switching device, wherein the protection branch extends from the input node to the second conductor being at the reference voltage level. The ESD stability of the described method can be improved by using altogether two ESD protection branches wherein a first branch directly connects the input node to the second conductor and a second branch indirectly connects the input node to the second conductor via an ohmic resistor. Anyway, an ESD protection has the advantage that logic devices being coupled directly or indirectly to the output node are less vulnerable to static electricity.

At this point it is noted that the invention may also be realized, when, in the embodiments described above wherein the type of switch element is named, a pmos device is replaced by an nmos device and vice versa. Such a modification may be in particular important when the operating voltage Vcc is negative with respect to gnd voltage level.

It has to be noted that certain embodiments of the invention have been described with reference to circuit arrangements and other embodiments of the invention have been described with reference to methods for transforming an input signal into a logical output signal. However, a person skilled in the art will gather from the above and the following description that, unless other notified, in addition to any combination of features belonging to one category of claims also any combination between features of the method claims and features of the circuit claims is possible and is considered to be disclosed with this application.

### BRIEF DESCRIPTION OF THE DRAWINGS

The aspects defined above and further aspects of the present invention are apparent from the examples of embodiment to be described hereinafter and are explained with reference to the examples of embodiment. The invention will be described in more detail hereinafter with reference to examples of embodiment but to which the invention is not limited.

FIG. 1 shows a circuit diagram of an electronic circuit arrangement according to an embodiment of the invention.

FIG. 2 shows a diagram depicting the switch levels of the circuit shown in FIG. 1 as a function of the operating voltage.

FIG. 3 shows a diagram depicting, as a function of the operating voltage, the hysteresis behavior of the circuit shown in FIG. 1 and of a reference circuit, respectively.

### DESCRIPTION OF EMBODIMENTS

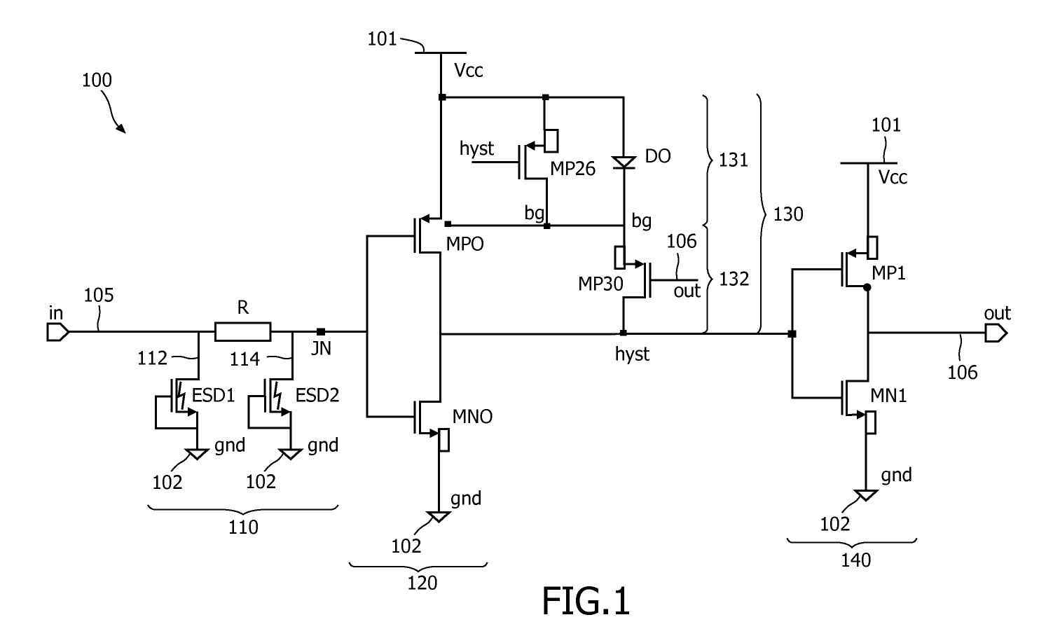

FIG. 1 shows a circuit diagram representing an electronic circuit arrangement 100 for transforming an input signal into a logical output voltage level. Since the circuit arrangement 100 may be used as an input stage for a variety of different logic devices the circuit arrangement 100 is also called an input cell.

The input cell 100 comprises a first conductor 101 providing an operating voltage Vcc. The input cell 100 further comprises a second conductor 102 providing a reference voltage, which according to the embodiment described here, is at ground level gnd. Although the two conductors 101 and 102 are not depicted as continuous conductor paths, each part of the two conductors 101 and 102 shown in FIG. 1 is electrically connected with other parts belonging to the same conductor, respectively.

The circuit arrangement 100 is subdivided into different circuit portions. Following an input terminal 105 representing a leadoff input node in, there is arranged an ESD protection portion 110. Following an ESD protected internal input node JN there is arranged a first inverter stage 120. The first inverter stage 120 is coupled with a voltage divider 130. Finally, the depicted input cell 100 comprises a second inverter stage 140 providing a logical output voltage level at a final output terminal out.

In the following the different circuit portions will be described.

The ESD protection portion 110 comprises two ESD circuit branches, a left ESD branch 112 and a right ESD branch 114. Each of the two branches 112 and 114 is equipped with an ESD protection device. The left branch 112 comprises a first ESD protection device ESD1, the right branch 112 comprises a second ESD protection device ESD2, respectively. The ESD protection devices may be all types of known ESD protection devices like diodes, other applicable semiconductor elements or any other arrangement for the purpose of protecting the first inverter stage 120 against ESD events. For instance, aside from a diode and a grounded-gate nMOS Transistor (ggNMOST), there may also be used a gate-coupled nMOS Transistor (gcNMOST), a Low Voltage Triggering Silicon Controlled Rectifier (LVT SCR) et cetera.

In between the two branches 112 and 114 there is arranged an ohmic resistor R, which is capable of providing a reasonable ESD decoupling between the leadoff input node in, which is connected to an output of an upstream electronic device (not shown), and the ESD protected internal input node JN representing the actual input of the first logic circuit portion 120 of the input cell 100.

Following the internal input node JN there is arranged the first inverter stage 120. The first inverter stage 120 comprises a MOS switch element MP0, which is a p-channel MOSFET. The p-channel MOSFET is also called briefly a pmos switch. The first inverter stage 120 further comprises a further MOS switch element MN0, which is an n-channel MOSFET. The n-channel MOSFET is also called briefly an nmos switch.

The source of the pmos switch MP0 is connected to the operating voltage Vcc. The drain of the pmos switch MP0 is connected to an internal output node hyst. The drain of the nmos switch MN0 is connected to the internal output node hyst. The source of the nmos switch MN0 is connected to ground gnd. The gates of MP0 and MN0 are both connected to the internal input node JN. The back gate of MP0 is connected to a divider output node bg. The back gate of MN0 and the source of MN0 are tied together.

The two switches MP0 and MN0 represent a CMOS inverter stage 120. The CMOS inverter stage 120 provides the advantage that during an normal operation mode of the input cell 100 there is always one of the two switches MP0 and MN0 closed such there is almost no static current flowing from Vcc to gnd via the first inverter stage 120.

In between the first conductor 101 being at Vcc and the internal output node hyst there is formed the voltage divider 130. The voltage divider 130 comprises an upper circuit portion 131 extending in between the first conductor 101 and the divider output node bg. The voltage divider 130 further comprises a lower circuit portion 132 extending in between the divider output node bg and the internal output node hyst.

The upper circuit portion 131 comprises in a parallel connection an upper pmos switch element MP26 and a diode D0. The source and the back gate of MP26 are connected to Vcc being present at the first conductor 101. The drain of MP26 is connected to the node bg. The gate of MP26 is connected to the internal output node hyst. The anode of DO is connected to Vcc, the cathode of DO is connected to divider output node bg, respectively.

The lower circuit portion 132 comprises a lower pmos switch element MP30. The source and the back gate of MP30 are connected to node bg. The drain of MP30 is connected to the node hyst. The gate of MP30 is connected to a final output node out. The final output node out is at a voltage level representing the logical inverted value of the voltage level being present at the internal output node hyst.

As can be seen from FIG. 1, the signal being present at the internal output node hyst is provided as an input signal to the second inverter stage 140. The second inverter stage 140 comprises a pmos switch element MP1 and an nmos switch element MN1.

The source and the back gate of MP1 are both connected to the operating voltage Vcc. The drain of MP1 is connected to the final output node out. The drain of the nmos switch MN1 is connected to the final output node out. The source and the back gate of MN1 is connected to ground gnd. The gates of MP1 and MN1 are both connected to the internal output node hyst.

Also the two switches MP1 and MN1 represent a CMOS inverter stage providing the same advantages, which have been described above with reference to the first inverter stage 120. The logical value being present at the final output node out can be delivered to an electronic device (not shown) connected downstream with respect to the input cell 100 via the final output terminal 106.

In the following the switching operation of the input cell 100 will be explained. Thereby, it will be assumed that there is no ESD event such that the voltage level being present at the leadoff input node in and the voltage level being present at the internal input node JN are practically the same.

At this point the typical behavior of pmos and nmos switches in digital electronics is briefly recapitulated in a simplified manner: A pmos switch is open when a low voltage state is applied to its gate and the pmos switch is closed when a high voltage state is applied to its gate. Accordingly, an nmos switch is closed when a low voltage state is applied to the gate of the nmos device and the nmos switch is open when a high voltage state is applied to its gate.

A) DC Condition with JN Being at Ground (Low)

If the internal input node JN is at ground, the pmos switch MP0 will be turned on (open) and the nmos switch MN0 will be turned off (closed). This causes the internal output node hyst as to be at a logical High state. This state is inverted by the second inverter stage 140 such that the final output node out is at a logical state Low.

Since the final output node is connected to the gate of MP30 via a feedback loop (not depicted in FIG. 1), the pmos switch MP30 will be open. In addition to the first inverter stage 120 also the open MP30 represents a contribution that the node hyst is at a logical state High (i.e. Vcc) and that the final output node is at ground gnd. Further, because MP30 is open, the node bg is also at a logical High state (i.e. VCC).

Since internal output hyst is connected directly to the gate terminal of MP26, the logical state High being present at the node hyst is applied to the gate of MP 26. This causes the pmos switch MP26 to be turned off. The diode DO ensures the node bg to be defined, in case both MP26 and MP30 are closed.

B) AC Condition with JN Performing a Transition from Low to High

If the internal input node JN rises from ground gnd to Vcc (transition from a logical Low state to a logical High state) the pmos switch MP0 will turn off and the nmos switch MN0 will turn on. This causes the voltage level of the internal output node hyst to decrease such that MP26 will be turned on. If one considers that MP30 is not yet turned off, a voltage division between the upper circuit portion 131 and the lower circuit portion 132 occurs causing the voltage level of the divider output node bg to decrease. Since the node bg represents also a MP0 back gate input node the switching threshold of MP0 will increase. This has the effect that it will be more difficult to turn off the pmos switch MP0.

In the meanwhile, the voltage level at the final output node out will increase. Since the final output node is connected to the gate of MP30, the pmos switch MP30 will be turned off. This leads to a cancellation of the voltage division and the whole input cell 100 reaches the other logical state, wherein the node JN (and the node in) are at a logical state High. In the other logical state, MP0 and MP30 are turned off and the node hyst is at ground level gnd. Hence, MP26 is fully turned on and node bg is again at Vcc. As a consequence, all pmos switches have their original threshold voltages (VTHP).

In other words, the pmos switch MP30 acts as a pull up device wherein the diode D0 and the pmos switch MP26 represent a degenerated source. Since the source of MP30 is also connected to the back gate of MP0, during a transition from a logical state Low to a logical state High the threshold voltage of MP0 is temporarily increased.

One important application of the circuit arrangement 100 is to provide an input cell for the AUP CMOS logic family described above. Therefore, the circuit has to fulfill a variety of different AUP specification limits, which are given in Table 1.

TABLE 1
AUP Specification limits for VIL and VIH.

| Vcc [V] | VIL | VIH |
|---|---|---|
| 0.8 | Gnd = 0 V | Vcc = 800 mV |
| 1.2 | 0.35 * Vcc = 420 mV | 0.65 * Vcc = 780 mV |
| 1.5 | 0.35 * Vcc = 525 mV | 0.65 * Vcc = 975 mV |
| 1.8 | 0.35 * Vcc = 630 mV | 0.65 * Vcc = 1.17 V |
| 2.5 | 700 mV | 1.6 V |
| 3.3 | 900 mV | 2 V |

Thereby, Vcc represents the operating voltage, VIL represents the switch value for a transition from High to Low and VIH represents the switch value for a transition from Low to High.

As will be illustrated in the following paragraphs, the circuit arrangement 100 fulfills the AUP specification limits given in table 1. In order to verify the AUP compatible electronic properties of the input cell 100 a simulation program called SPICE was employed. This program or equivalent programs are well known to experts in the field of designing electronic circuits.

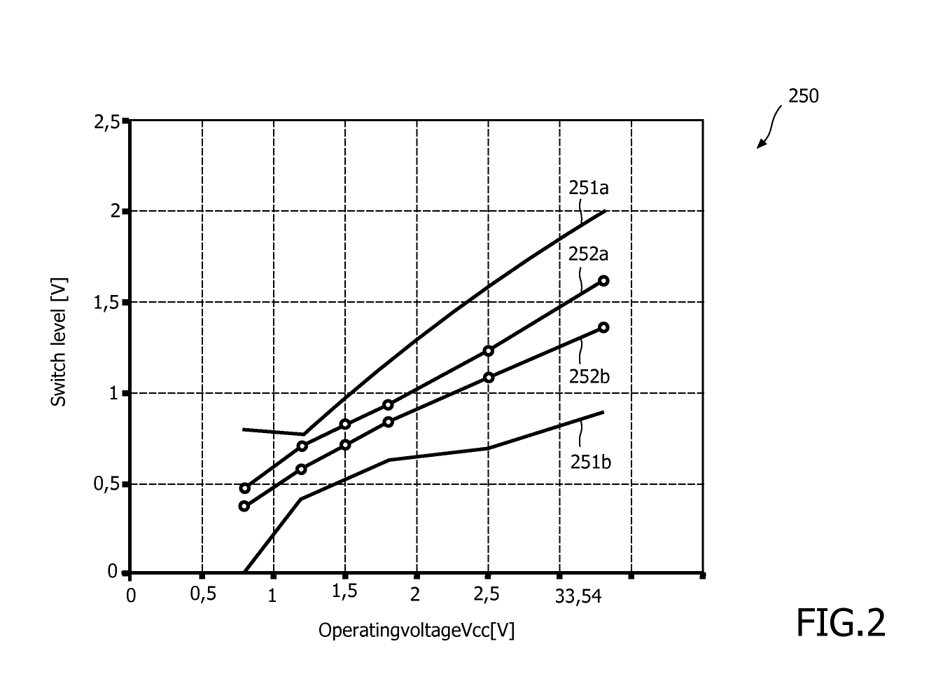

FIG. 2 shows a diagram 250 wherein the switch levels of the circuit 100 are depicted as a function of the operating voltage Vcc. The results are based on a so-called Min/Max analysis of the switch levels for different semiconductor process cases over a total temperature range between −40° C. and +85° C. The process cases under study were the “SLOW” process, the “NOMINAL” process and the “FAST” process. These processes represent different types of Silicon due to a statistical spread in the Silicon manufacturing process.

The curve 251a shows the AUP specification switch level VIH for a transition from Low to High. The 251b shows the AUP specification switch level VIL for a transition from High to Low.

The curves 252a and 252b show the corresponding switch level of the input cell 100. Thereby, the curve 252a shows the threshold voltage VTHPLUS for a transition of the input cell 100 from a logical state Low to a logical state High. The curve 252b shows the threshold voltage VTHMIN for a transition from High to Low. As can be seen from FIG. 2 the two curves 252a and 252b lie well within the AUP specification limits. Therefore, the circuit arrangement 100 can be used as an input cell for AUP devices.

Table 2 shows the exact values of the simulation results depicted in FIG. 2 for different process corners.

TABLE 2
Simulation results for process corners (see FIG. 2), temperature and
operating voltage Vcc.

| | VTHMIN [V] | | | VTHPLUS [V] | | |
|---|---|---|---|---|---|---|
| Vcc [V] | Min | Nominal | Max | Min | Nominal | Max |
| 0.8 | 0.223 | 0.366 | 0.375 | 0.457 | 0.471 | 0.563 |
| 1.2 | 0.501 | 0.577 | 0.637 | 0.607 | 0.695 | 0.771 |
| 1.5 | 0.638 | 0.709 | 0.779 | 0.722 | 0.807 | 0.897 |
| 1.8 | 0.734 | 0.824 | 0.911 | 0.822 | 0.913 | 1.010 |
| 2.5 | 0.954 | 1.051 | 1.142 | 1.079 | 1.193 | 1.302 |
| 3.3 | 1.173 | 1.297 | 1.420 | 1.359 | 1.543 | 1.721 |

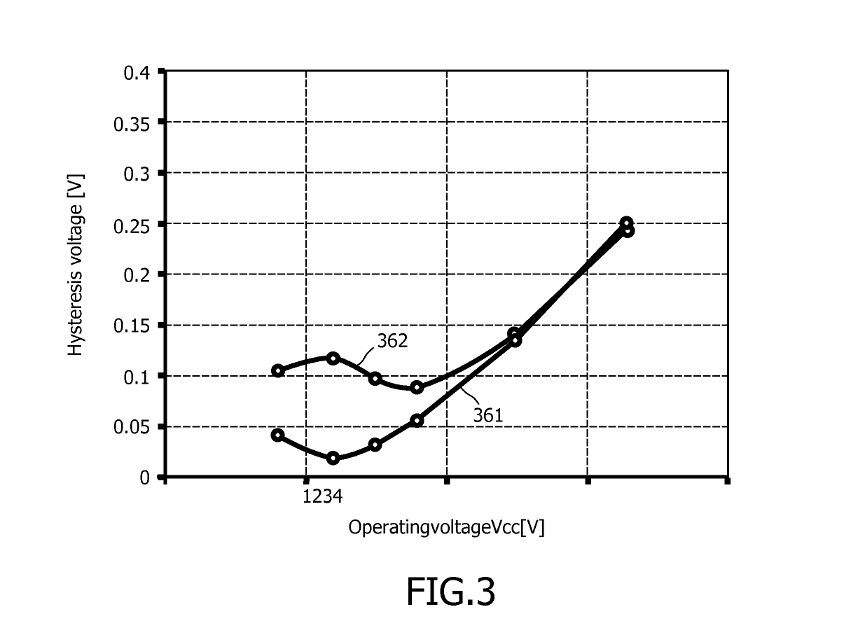

FIG. 3 shows a diagram 360 depicting the hysteresis behavior as a function of the operating voltage Vcc. The hysteresis behavior comprises the voltage difference between VTHMIN and VTHPLUS. The behavior of a known standard input cell with a comparable hysteresis at 3.3V is denoted with the reference numeral 361. The hysteresis behavior of the input cell 100 is denoted with the reference numeral 362. It can be observed that for lower voltages, a hysteresis action is sustained, whereas the hysteresis action of the known standard cell diminishes fast. From the simulations, it can be concluded that the guaranteed minimum hysteresis over the total operating voltage range is significantly higher than for the known standard input cell. The actual values of the simulation can be found in Table 3.

TABLE 3
Simulation results for the hysteresis behavior of the input cell 100 for a
variation of opposite process corners, temperature and operating
voltages Vcc.

| | VHYS | | |
|---|---|---|---|
| Vdd [V] | Min | Nominal | Max |
| 0.8 | 0.094 | 0.106 | 0.243 |
| 1.2 | 0.101 | 0.119 | 0.128 |
| 1.5 | 0.087 | 0.098 | 0.124 |
| 1.8 | 0.084 | 0.089 | 0.104 |
| 2.5 | 0.099 | 0.141 | 0.181 |
| 3.3 | 0.175 | 0.246 | 0.309 |

Table 4 shows further simulation results representing a further characteristic value for input cells. This value is called ΔIcc and it is defined by the difference between the current drawn from Vcc during a switching event and the static current. In order to allow for a comparison between the improved input cell 100 and a known standard or reference input cell the simulation results for both input cells are depicted. The value for ΔIcc is given for three different process corners and for three temperatures, −40° C., 25° C. and 85° C., respectively.

TABLE 4
Actual values for the simulation results for ΔIcc [A] for different process
corners and for different temperatures.

| | known reference input cell | | | Improved input cell | | |
|---|---|---|---|---|---|---|
| | −40° C. | 25° C. | 85° C. | −40° C. | 25° C. | 85° C. |
| FAST | 8.26E−07 | 4.19E−06 | 9.66E−06 | 6.17E−07 | 3.14E−06 | 7.23E−06 |
| NOMINAL | 1.14E−07 | 1.13E−06 | 3.72E−06 | 8.53E−08 | 8.47E−07 | 2.78E−06 |
| SLOW | 1.38E−08 | 2.60E−07 | 1.26E−06 | 1.03E−08 | 1.94E−07 | 9.37E−07 |

As can be seen from table 4, ΔIcc of the improved input cell 100 is approximately 25% lower than for the reference input cell. The AUP specification limit is 50 μA. The simulation results for the improved input cell show that the maximum value for ΔIcc is 7.2 μA.

Last but not least it is mentioned that there have been performed simulations also for the dissipation capacitance and the AC behavior of the improved input cell 100.

Compared to the reference design, the Capacitance Power Dissipation (CPD) of the improved input cell 100 is approximately 25% larger. For the nominal operating voltage of 3.3V, the CPD of the improved input cell 100 is approximately 900 fF.

The AC behavior has been simulated with a reference load of 200 fF, which is arranged downstream of the input cell 100 and which is connected to the final output node out shown in FIG. 1. It has been found out that the propagation delay from the leadoff input node in to the final output node out is comparable with the propagation delay of the reference input cell described above.

It should be noted that the invention is not limited to the exemplary examples shown in the figures. In particular, it is clear for a person skilled in the art that the invention may also be realized with other switching devices like ordinary transistors or other types of Field Effect Transistors (FET), e.g. Junction FET. It is also clear that the invention can also be realized when, in the circuit arrangement 100 shown in FIG. 1, a pmos device is replaced by an nmos device and vice versa. Such a modification may be in particular important when the operating voltage Vcc is negative with respect to gnd voltage level.

Further, it should be noted that the term “comprising” does not exclude other elements or steps and the “a” or “an” does not exclude a plurality. Also elements described in association with different embodiments may be combined. It should also be noted that reference signs in the claims should not be construed as limiting the scope of the claims.

In order to recapitulate the above described embodiments of the present invention one can state:

An improved input cell 100 has been designed that has an unprecedented high hysteresis over the total operating range. This is realized by modifying the input threshold of the pmos switching device MP0 during the Low-High transition. Thereby, the hysteresis behavior is significantly improved. Simulations showed that for typical cases over the total voltage range a minimum hysteresis of 90 mV might be achieved. The performance of the input cell is comparable to that of a known standard or reference input cell. The switch levels are within specification limits over the total range for operating voltages and for all relevant process corners being existent in a corresponding silicon semiconductor manufacturing process. Compared to the known reference input cell the ΔIcc value is decreased by 25%. This is based on the modification of the pmos switch MP0 wherein the back gate voltage is adjusted during the Low-High transition. This causes a temporarily increased threshold voltage for closing MP0 during the transition. Further, the CPD is 25% larger than for the reference input cell and the speed performance is comparable to the reference input cell. The improved input cell can fulfill all requirements that exist for the AUP family.

1. Electronic circuit arrangement for transforming an input signal into a logical output voltage level, the electronic circuit arrangement comprising:
a first conductor adapted to be connected to an operating voltage level,
a second conductor adapted to be connected to a reference voltage level,
an inverter stage connected in between the first conductor and the second conductor the inverter stage including a MOS switch element which comprises
a first terminal being connected to the first conductor,
a second terminal being connected to an output node,
a gate terminal being connected to an input node, and
a back gate terminal, and
a voltage divider connected in between the first conductor and the output node wherein the voltage divider provides a divider output node being connected to the back gate terminal of the MOS switch element.

2. The electronic circuit arrangement as set forth in claim 1, wherein the MOS switch element is a p-channel MOSFET, the source of which being connected to the first conductor and the drain of which being connected to the output node.

3. The electronic circuit arrangement as set forth in claim 1, wherein the inverter stage includes a further MOS switch element, which comprises
a first terminal being connected to the output nodes,
a second terminal being connected to the reference voltage level, and
a gate terminal being connected to the input node.

4. The electronic circuit arrangement as set forth in claim 3, wherein the MOS switch element is an n-channel MOSFET, the drain of which being connected to the output node and the source of which being connected to the second conductor.

5. The electronic circuit arrangement as set forth in claim 1, wherein the voltage divider comprises
an upper circuit portion connected in between the first conductor and the divider output node, and
a lower circuit portion connected in between the divider output node and the output node, wherein the upper circuit portion includes an upper switch element, which comprises—a first terminal being connected to the first conductor,
a second terminal being connected to the divider output node, and
a gate terminal being connected to the output node.

6. The electronic circuit arrangement as set forth in claim 5, wherein the upper switch element is a p-channel MOSFET, the source of which being connected to the first conductor and the drain of which being connected to the divider output node.

7. The electronic circuit arrangement as set forth in claim 5, wherein the lower circuit portion includes
a lower switch element, which comprises
a first terminal being connected to the divider output node,
a second terminal being connected to the output node, and
a gate terminal being connected to a node, which comprises a voltage level representing a logical inverted signal of the signal being present at the output node.

8. The electronic circuit arrangement as set forth in claim 7, wherein the lower switch element is a p-channel MOSFET, the source of which being connected to the divider output node and the drain of which being connected to the output node.

9. The electronic circuit arrangement as set forth in claim 5, wherein the upper circuit portion includes a diode, which is connected in parallel to the upper switch element.

10. The electronic circuit arrangement as set forth in claim 1, further comprising an additional inverter stage connected in between the first conductor and the second conductor the additional inverter stage including an additional MOS switch element which comprises
a first terminal being connected to the first conductor,
a second terminal being connected to a final output node, and
a gate terminal being connected to the output node.

11. The electronic circuit arrangement as set forth in claim 10, wherein the additional MOS switch element is a p-channel MOSFET, the source of which being connected to the first conductor and the drain of which being connected to the final output node.

12. The electronic circuit arrangement as set forth in claim 10, wherein the additional inverter stage includes a further additional MOS switch element, which comprises
a first terminal being connected to the final output node,
a second terminal being connected to the reference voltage level, and
a gate terminal being connected to the output node.

13. The electronic circuit arrangement as set forth in claim 12, wherein the further additional MOS switch element is an n-channel MOSFET, the drain of which being connected to the final output node and the source of which being connected to the second conductor.

14. The electronic circuit arrangement as set forth in claim 1, further comprising a first Electro Static Discharge protection extending between the input node and the second conductor.

15. The electronic circuit arrangement as set forth in claim 14, further comprising a second Electro Static Discharge protection extending between a leadoff input node and the second conductor, wherein
the leadoff input node is adapted to be connected to an input signal to the electronic circuit arrangement and
the leadoff input node and the input node are connected to each other via a resistor.

16. Method for transforming an input signal into a logical output voltage level, the method comprising the steps of:
applying an input signal to an input node, the input node being connected to an inverter stage, which is connected in between a first conductor being at an operating voltage level and a second conductor being at a reference voltage level, wherein the inverter stage includes a MOS switch element, which comprises—a first terminal being connected to the first conductor—a second terminal being connected to an output node,
a gate terminal being connected to the input node, and
a back gate terminal,
and when the input signal accomplishes a transition from an input level Low to an input level High, the voltage level of a divider output node being connected to the back gate terminal of the MOS switch element is temporarily lowered such that the threshold voltage of the MOS switch element is temporarily increased.

17. Method as set forth in claim 16, further comprising the step of generating the voltage level of the divider output node by means of a voltage division between the operating voltage level and the voltage level being present at the output node.

18. Method as set forth in claim 17, wherein the step of generating the voltage level of the divider output node is carried out by means of a voltage divider, the voltage divider comprising
an upper circuit portion connected in between the first conductor and the divider output node, and
a lower circuit portion connected in between the divider output node and the output nodes.

19. Method as set forth in claim 16, further comprising the steps of inverting the voltage level being present at the output node and providing the inverted voltage level at a final output node.

20. Method as set forth in claim 16, further comprising the step of protecting the input node from Electro Static Discharge currents.
